(19) United States
(12) Patent Application Publication
(10) Pub. No.: US 2025/0164981 A1
(43) Pub. Date: May 22, 2025

(54) OPTIMIZATION METHOD FOR VACUUM PLATING PROCESS

(71) Applicant: Industrial Technology Research Institute, Hsinchu (TW)

(72) Inventors: Shih-Chin Lin, New Taipei City (TW); Wen-Jun Chen, Kaohsiung City (TW); Ching-Chiun Wang, Miaoli County (TW); Chih-Ming Ho, Los Angeles, CA (US); Da-Jeng Yao, Taipei City (TW)

(73) Assignee: Industrial Technology Research Institute, Hsinchu (TW)

(21) Appl. No.: 18/951,650

(22) Filed: Nov. 19, 2024

Related U.S. Application Data
(60) Provisional application No. 63/601,710, filed on Nov. 21, 2023.

(51) Int. Cl. G05B 19/418; C23C 14/54; C23C 16/52

(52) U.S. Cl. CPC G05B 19/41885; C23C 14/54; C23C 16/52; G05B 2219/45031

(57) ABSTRACT

An optimization method for a vacuum plating process includes following steps. A property of a thin film to be optimized is determined. According to the property of the thin film to be optimized, process parameters and a level of each of the process parameters are determined. M sets of experiments are designed, where M is a positive integer, M is positively related to a number of the process parameters, but M is not related to a number of the level of the process parameters. The M sets of experiments are performed to obtain M sets of test films and the property of each of the test films are measured or calculated. Process parameters used in the M sets of experiments and the property of the M sets of test films are fitted with a multi-dimensional quadratic transformation function to obtain a first fitting function. The first fitting function is dynamically modified using an iteration method to obtain a best fitting function. A multi-dimensional response surface diagram is illustrated using the best fitting function to determine an optimal process parameter combination.

### CROSS-REFERENCE TO RELATED APPLICATION

This application claims the priority benefit of U.S. provisional application Ser. No. 63/601,710, filed on Nov. 21, 2023. The entirety of the above-mentioned patent application is hereby incorporated by reference herein and made a part of this specification.

### BACKGROUND

### Technical Field

This disclosure relates to an optimization method, and in particular to an optimization method of a vacuum plating process.

### Description of Related Art

Thin films made by vacuum plating systems have been widely used in various fields, such as semiconductor devices, solar cells, memory, photoconductive materials, and microelectromechanical materials. With different applications, it is necessary to adjust different process parameters, types of raw materials and additive amounts to meet the needs of various thin films. In order to obtain an optimal combination of parameters, a large number of experimental trials and errors are required, which are costly in terms of manpower, resources and time. Moreover, this trial-and-error method lacks the rules to effectively link process parameters to thin film properties, which makes it difficult to apply to other thin films or to make predictions. Therefore, how to improve the efficiency of thin film process control and the accuracy of prediction is an issue that needs to be improved.

### SUMMARY

The disclosure provides an optimization method for a vacuum plating process, capable of improving efficiency of optimization and accuracy of prediction.

The optimization method for the vacuum plating process of the disclosure includes following steps. A property of a thin film to be optimized is determined. According to the property of the thin film to be optimized, process parameters and a level of each of the process parameters are determined. M sets of experiments are designed, where M is a positive integer, M is positively related to a number of the process parameters, but M is not related to a number of the level of the process parameters. The M sets of experiments are performed to obtain M sets of test films and the property of each of the test films are measured or calculated. Process parameters used in the M sets of experiments and the property of the M sets of test films are fitted with a multi-dimensional quadratic transformation function to obtain a first fitting function. The first fitting function is dynamically modified using an iteration method to obtain a best fitting function. A multi-dimensional response surface diagram is illustrated using the best fitting function to determine an optimal process parameter combination.

Based on the above, the optimization method for the vacuum plating process of the disclosure can fit a small amount of experiment data to obtain an accurate fitting function by fitting the multi-dimensional quadratic transformation function and making dynamic iterative corrections. In this way, the efficiency of optimization and the accuracy of prediction may be effectively improved.

### BRIEF DESCRIPTION OF THE DRAWINGS

FIG. 1 is a schematic flow chart of an optimization method of a vacuum plating process according to an embodiment of the disclosure.

FIG. 2 is a three-dimensional surface diagram of a process parameter and a thin film characteristic according to an embodiment of the disclosure.

FIG. 3 is a three-dimensional surface diagram of RF power, substrate temperature, and deposition rate according to an experiment example.

FIG. 4 is a three-dimensional surface diagram of RF power, reaction chamber pressure, and deposition rate according to an experiment example.

FIG. 5 is a three-dimensional surface diagram of RF power, flow ratio of N₂ and SiH₄, and deposition rate according to an experiment example.

FIG. 6 is a three-dimensional surface diagram of RF power, mass flow rate of N₂, and deposition rate according to an experiment example.

FIG. 7 is a three-dimensional surface diagram of substrate temperature, reaction chamber pressure, and deposition rate according to an experiment example.

FIG. 8 is a three-dimensional surface diagram of flow ratio of N₂ and SiH₄, substrate temperature, and deposition rate according to an experiment example.

FIG. 9 is a three-dimensional surface diagram of flow ratio of N₂ and SiH₄, reaction chamber pressure, and deposition rate according to an experiment example.

FIG. 10 is a three-dimensional surface diagram of mass flow rate of N₂, substrate temperature, and deposition rate according to an experiment example.

FIG. 11 is a three-dimensional surface diagram of reaction chamber pressure, mass flow rate of N₂, and deposition rate according to an experiment example.

FIG. 12 is a three-dimensional surface diagram of flow ratio of N₂ and SiH₄, mass flow rate of N₂, and deposition rate according to an experiment example.

### DESCRIPTION OF THE EMBODIMENTS

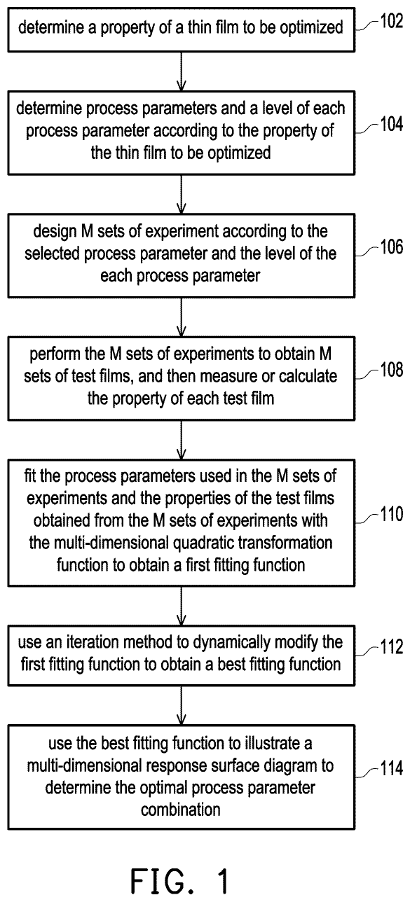

FIG. 1 is a schematic flow chart of an optimization method of a vacuum plating process according to an embodiment of the disclosure.

Please refer to FIG. 1. In step 102, a property of a thin film to be optimized is determined, such as the thickness, residual stress, deposition rate, uniformity, refractive index, resistance value, ratio of its components, or other appropriate characteristics.

Please refer to FIG. 1. In step 104, process parameters and a level of each process parameter are determined according to the property of the thin film to be optimized. Relevant process parameters and their levels can be selected according to past experience, existing resources, etc. In some embodiments, the process parameters may include process pressure, process temperature, reactant flow rate (such as mass flow rate, volume flow rate, or the like), type of reactant, reactant addition ratio, radio frequency power, or other suitable process parameters. In some embodiments, the level of the each process parameter can be set as two levels (low, high) or three levels (low, medium, high), and different process parameters can have different number of levels.

In some embodiments, the value of the level of the each process parameter can be designed within its adjustable range. For example, the adjustable range of the process temperature in the vacuum plating system is between 25° C. and 800° C., then 200° C. and 500° C. can be set as two levels of process temperature. The setting of level can be selected according to the understanding of the process, the scope to be explored, etc., without special restrictions.

Please refer to FIG. 1. In step 106, M sets of experiment are designed according to the selected process parameter and the level of the each process parameter. M is a positive integer, and M is positively related to a number of the process parameters, but M is not related to a number of levels of the process parameters. In some embodiments, M is related to a number of unknown coefficients of a subsequent multi-dimensional quadratic transformation function to be fitted.

In some embodiments, the multi-dimensional quadratic transformation function can be represented by the following formula (a):

$$E = {c}_{0} + {\sum }_{i = 1}^{n} {c}_{i} {f}_{i} + {\sum }_{i = 1}^{n} {c}_{ii} {f}_{i}^{2} + {\sum }_{i = 1}^{n} {\sum }_{j = 1}^{n} {c}_{ij} {f}_{i} {f}_{j} , \qquad Formula ( a )$$

where E is the property of the thin film to be optimized, n is the number of process parameters, fᵢ and fⱼ are process parameters, and c₀, cᵢ, cᵢᵢ, and cᵢⱼ are unknown coefficients. Therefore, for this embodiment, in order to fit the above formula (a), M is at least (n²+3n+2)/2. Compared with the traditional trial and error method, the number of experiments may be greatly reduced by fitting the above multi-dimensional quadratic transformation function.

In some embodiments, some items of the above formula (a) can be omitted to further reduce the number of experiments. For example, the linear term in formula (a) can be ignored, that is, the multi-dimensional quadratic transformation function can be expressed by the following formula (b):

$$E = {c}_{0} + {\sum }_{i = 1}^{n} {c}_{ii} {f}_{i}^{2} + {\sum }_{i = 1}^{n} {\sum }_{j = 1}^{n} {c}_{ij} {f}_{i} {f}_{j} , \qquad Formula ( b )$$

where E is the property of the thin film to be optimized, n is the number of process parameters, fᵢ and fⱼ are process parameters, and c₀, cᵢᵢ, and cᵢⱼ are unknown coefficients. Therefore, for this embodiment, in order to fit the above formula (b), M is at least (n²+n+2)/2.

In some embodiments, the experiment design method may adopt the Orthogonal Array Composite Design (OACD) method or other suitable design methods, but the disclosure is not limited thereto.

Please refer to FIG. 1. In step 108, the M sets of experiments designed above are performed to obtain M sets of test films, and then the property of each test film is measured or calculated.

Please refer to FIG. 1. In step 110, the process parameters used in the M sets of experiments and the properties of the test films obtained from the M sets of experiments are fitted with the multi-dimensional quadratic transformation function to obtain a first fitting function. In some embodiments, multi-dimensional regression analysis can be used to fit the multi-dimensional quadratic transformation function, but the disclosure is not limited thereto. In other embodiments, other regression models, neural network-like models or other suitable means can also be used to perform the fitting.

Please refer to FIG. 1. In step 112, an iteration method is used to dynamically modify the first fitting function to obtain a best fitting function. For example, the first fitting function can be used to determine a first optimal parameter combination. The method of determining the first optimization parameter combination is the same as step 114 described later, which will be described later. Next, the M+1^{th} set of experiments is performed with the first optimal parameter combination to obtain the M+1^{th} set of test film, and the property of the test film is measured or calculated. After that, the process parameters used in the M+1^{th} set of experiments and the property of the test film obtained from the M+1^{th} set of experiments are second-fitted with the multi-dimensional quadratic transformation function to obtain a second fitting function. By analogy, the above dynamic iteration method can be repeated to perform multiple fit corrections to improve the fitting effect and obtain the best fitting function.

In some embodiments, a determination coefficient (i.e., R²) can be used to determine the fit property of the fitting function. When the determination coefficient is closer to 1, it means that the fit property of the fitting function is better. When the determination coefficient is closer to 0, it means that the fit property of the fitting function is worse. The determination coefficient can be expressed as follows:

$${R}^{2} = 1 - \frac{{SS}_{res}}{{SS}_{tot}} ,$$

where SSₜₒₜ=Σᵢ₌₁^{m}(yᵢ−y_{avg})², SSᵣₑₛ=Σᵢ₌₁^{m}eᵢ²,
where m is the total number of experiments, yᵢ is the thin film property value actually measured in the i^{th} set of experiments, y_{avg} is the average of the thin film property values actually measured in all experiments, and eᵢ is the difference between the thin film property value actually measured in the i^{th} set of experiments and the thin film property value of the i^{th} set of experiments predicted by the fitting function.

In some embodiments, as the number of iterations increases, the determination coefficient (i.e., R²) of the corresponding fitting function becomes closer to 1. That is, the determination coefficient (i.e., R²) of the second fitting function (or the determination coefficient of the best fitting function) is greater than the determination coefficient of the first fitting function. In some embodiments, if the determination coefficient of the second fitting function is smaller than the determination coefficient of the first fitting function (that is, the determination coefficient of the fitting function obtained after iteration is smaller than the determination coefficient of the fitting function obtained before iteration), it is necessary to confirm whether there is any abnormal condition in the experiment process. If the abnormal condition is ruled out, it is necessary to review the experimental design, for example, whether the selection of process parameters and the selection of level of each process parameter are appropriate, etc., to judge whether to redesign the experiment.

In some embodiments, multiple iterations can be performed until the determination coefficient (i.e., R²) of the obtained fitting function is greater than or equal to a target value, then the fitting function this time is the best fitting function. In some embodiments, the target value of the determination coefficient is, for example, 0.90, 0.95, 0.98, or other suitable values, but the disclosure is not limited thereto. In some embodiments, the best fitting function is obtained by fitting data from at least M+p experiments, where M is the number of initial experiment sets and p is the number of iterations.

In some embodiments, if the determination coefficient (i.e., R²) of the fitting function obtained by the k^{th} iteration is smaller than the determination coefficient of the fitting function obtained by the k−1^{th} iteration, or the best parameter combination obtained by the k^{th} iteration is the same as the best parameter combination obtained by the k−1^{th} iteration, the fitting function obtained by the k−1^{th} iteration can be used as the best fitting function, where k is a positive integer.

In the embodiment where the multi-dimensional quadratic transformation function is represented by formula (a), the best fitting function can be represented by the following formula 1,

$$E = ( {c}_{0 , 0} + Δ {c}_{0} ) + {\sum }_{i = 1}^{n} ( {c}_{i , 0} + Δ {c}_{i} ) {f}_{i} + {\sum }_{i = 1}^{n} ( {c}_{ii , 0} + Δ {c}_{ii} ) {f}_{i}^{2} + {\sum }_{i = 1}^{n} {\sum }_{j = 1}^{n} ( {c}_{ij , 0} + Δ {c}_{ij} ) {f}_{i} {f}_{j} , \qquad [ Formula 1 ]$$

where E is the property of the thin film to be optimized, n is the number of process parameters, fᵢ and fⱼ are process parameters, and c_{0,0}, c_{i,0}, c_{ii,0}, and c_{ij,0} are coefficients obtained by fitting the data of the M sets of experiments (i.e., the coefficients of the first fitting function),

$$Δ {c}_{0} is {\sum }_{k = 1}^{p} ( {c}_{0 , k} - {c}_{0 , k - 1} ) , Δ {c}_{i , k} is {\sum }_{k = 1}^{p} ( {c}_{i , k} - {c}_{i , k - 1} ) , \\ Δ {c}_{ii , k} is {\sum }_{k = 1}^{p} ( {c}_{ii , k} - {c}_{ii , k - 1} ) , Δ {c}_{ij , k} is {\sum }_{k = 1}^{p} ( {c}_{ij , k} - {c}_{ij , k - 1} ) ,$$

where c_{0,k}, c_{i,k}, c_{ii,k}, and c_{ij,k} are coefficients obtained by the k^{th} iteration and fit, c_{0,k-1}, c_{i,k-1}, C_{ii,k-1}, and c_{ij,k-1} is the coefficient obtained by the k−1^{th} iteration and fit, and p is the number of iterations.

In the embodiment where the multi-dimensional quadratic transformation function is represented by formula (b), the best fitting function can be represented by the following formula 2,

$$E = ( {c}_{0 , 0} + Δ {c}_{0} ) + {\sum }_{i = 1}^{n} ( {c}_{ii , 0} + Δ {c}_{ii} ) {f}_{i}^{2} + {\sum }_{i = 1}^{n} {\sum }_{j = 1}^{n} ( {c}_{ij , 0} + Δ {c}_{ij} ) {f}_{i} {f}_{j} , \qquad [ Formula 2 ]$$

where E is the property of the thin film to be optimized, n is the number of process parameters, fᵢ and fⱼ are process parameters, c_{0,0}, c_{ii,0}, and c_{ij,0} are coefficients obtained by fitting the data of the M sets of experiments (i.e., the fitting coefficients of the first fitting function),

$$Δ {c}_{0} is {\sum }_{k = 1}^{p} ( {c}_{0 , k} - {c}_{0 , k - 1} ) , Δ {c}_{ii , k} is {\sum }_{k = 1}^{p} ( {c}_{ii , k} - {c}_{ii , k - 1} ) , \\ Δ {c}_{ij , k} is {\sum }_{k = 1}^{p} ( {c}_{ij , k} - {c}_{ij , k - 1} ) ,$$

where c_{0,k}, c_{ii,k}, and c_{ij,k} are fitting coefficients obtained by the k^{th} iteration, c_{0,k-1}, c_{ii,k-1}, and c_{ij,k-1} are the fitting coefficients obtained by the k−1^{th} iteration, and p is the number of iterations.

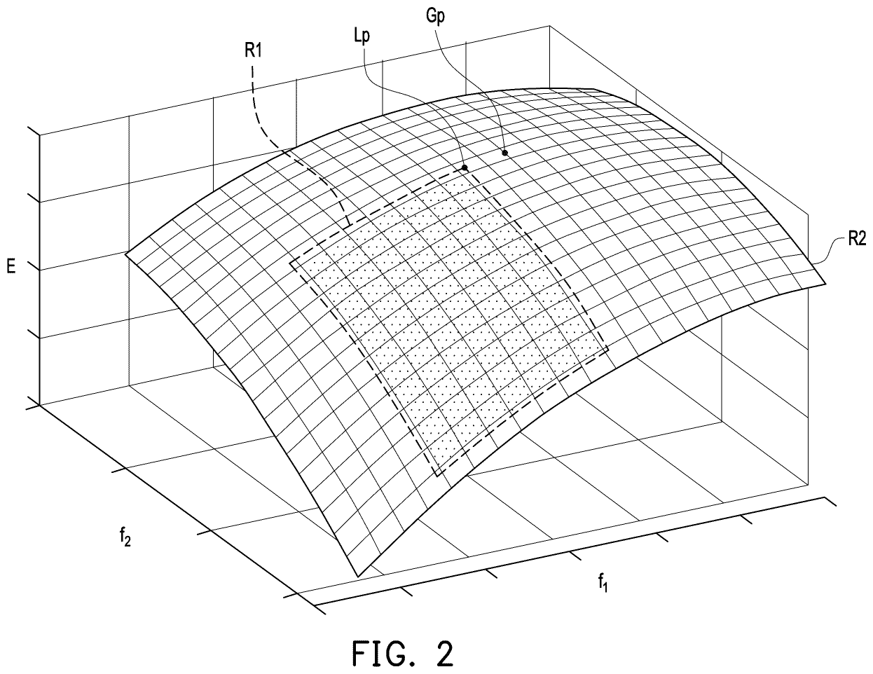

Please refer to FIG. 1. In step 114, the best fitting function is used to illustrate a multi-dimensional response surface diagram to determine the optimal process parameter combination. For example, two process parameters can be grouped together, and when the values of the remaining process parameters are fixed to the optimal parameter combination, a three-dimensional response surface diagram can be illustrated with the thin film property, as shown in FIG. 2. The trend of the image is used to understand the relationship between each process parameter and thin film properties, and to find an optimal parameter combination Lp within a process range R1. In some embodiments, it is also possible to extrapolate the process parameters to a full range R2 by the extrapolation difference method, and obtain an optimal process parameter combination Gp in the full range R2. Here, the full range refers to the maximum adjustable range of process parameters, which may be related to the capability of the machine or equipment. For example, the full range of the process pressure can be in the range from 0.0001 Torr to 50 Torr, the full range of the process temperature be in the range from room temperature to 800° C., the full range of the reactant mass flow rate can be in the range from 2 sccm to 5 slm, and the full range of the radio frequency power can in the range from 10 W to 6 KW, but the disclosure is not limited thereto.

In some embodiments, through the best fitting function, the coefficient magnitude of each process parameter can be compared and analyzed to understand the degree of influence of each process parameter on the thin film property. For example, the greater the absolute value of the coefficient corresponding to the process parameter, the greater the impact on the thin film property; conversely, the smaller the absolute value of the coefficient corresponding to the process parameter, the smaller the impact on the thin film property.

In some embodiments, the optimization method can be applied to various vacuum plating processes, such as physical vapor deposition, thermal evaporation, electron beam evaporation, ion beam assisted evaporation, molecular beam epitaxy, pulse laser coating chemical vapor deposition, plasma enhanced chemical vapor deposition, metal organic chemical vapor deposition and atomic layer deposition or other suitable vacuum plating process.

Below, the optimization method for the vacuum plating process of the disclosure is explained in detail through an experiment example. However, the following experiment example is not intended to limit the disclosure.

This experiment example aims to optimize the deposition rate of silicon nitride thin film formed by plasma enhanced chemical vapor deposition (PECVD) method, in which the reactants for forming silicon nitride thin film include N₂ and SiH₄. Five process parameters were selected for experiment design from Group 1 to Group 26, as shown in Table 1 below, in which the process parameters include RF power, reaction chamber pressure, substrate temperature, flow ratio of N₂ and SiH₄, and mass flow rate of N₂, and each process parameter is set to three levels. After that, a silicon nitride thin film was prepared according to the experimental design of Group 1 to Group 26, and its deposition rate was measured, which are recorded in Table 1. The data from experiments 1 to 26 in the following table were then used to fit the multi-dimensional quadratic transformation function represented by formula (a) and to predict the optimal parameter combination. A silicon nitride thin film was prepared with this optimal process parameter combination and its deposition rate was measured, which is recorded in the 27^{th} group of experiments in Table 1. Then, the data from group 1 to group 27 are then used to fit the multi-dimensional quadratic transformation function represented by formula (a), an iterative correction is performed, the optimal parameter combination obtained after the correction is the same as that analyzed in group 1 to group 26, and therefore the iteration is stopped. The best fitting function is obtained as follows, and its determination coefficient is 0.98:

$$E = ( - 6 * {10}^{- 4} ) + 0.001 {f}_{1} - ( 2 * {10}^{- 6} ) {{f}_{1}}^{2} + 0.002 {f}_{2} - ( 9 * {10}^{- 6} ) {{f}_{2}}^{2} + ( 2 * {10}^{- 4} ) {f}_{3} + ( 6 * {10}^{- 4} ) {{f}_{3}}^{2} + 0.012 {f}_{4} + ( 9 * {10}^{- 5} ) {{f}_{4}}^{2} - 0.002 {f}_{5} - ( 4 * {10}^{- 7} ) {{f}_{5}}^{2} - ( 1 * {10}^{- 5} ) {f}_{4} {f}_{5} + 0.002 {f}_{3} {f}_{5} - 0.038 {f}_{3} {f}_{4} + ( 5 * {10}^{- 6} ) {f}_{2} {f}_{5} + ( 2 * {10}^{- 5} ) {f}_{2} {f}_{4} + ( 5 * {10}^{- 4} ) {f}_{2} {f}_{3} + ( 3 * {10}^{- 6} ) {f}_{1} {f}_{5} - ( 4 * {10}^{- 5} ) {f}_{1} {f}_{4} + ( 9 * {10}^{- 4} ) {f}_{1} {f}_{3} + ( 2 * {10}^{- 6} ) {f}_{1} {f}_{2} .$$

TABLE 1

| | process parameter | | | | | thin film |
|---|---|---|---|---|---|---|
| | | f₂ | | | | property |
| | f₁ | reaction | f₃ | f₄ | f₅ | E |
| | RF | chamber | substrate | flow ratio | mass flow | deposition |
| | power | pressure | temperature | of N₂ | rate of | rate |
| experiment | (W) | (Torr) | (° C.) | and SiH₄ | N₂ (sccm) | (nm/sec) |
| 1 | 200 | 0.2 | 200 | 50 | 500 | 0.329 |
| 2 | 600 | 0.2 | 200 | 10 | 100 | 0.450 |
| 3 | 200 | 0.5 | 200 | 50 | 100 | 0.189 |
| 4 | 600 | 0.5 | 200 | 10 | 500 | 1.129 |
| 5 | 200 | 0.35 | 200 | 50 | 300 | 0.315 |
| 6 | 600 | 0.5 | 200 | 10 | 300 | 0.907 |
| 7 | 400 | 0.2 | 200 | 50 | 500 | 0.371 |
| 8 | 600 | 0.35 | 200 | 30 | 500 | 0.570 |
| 9 | 400 | 0.5 | 200 | 30 | 100 | 0.283 |
| 10 | 200 | 0.2 | 200 | 10 | 100 | 0.311 |
| 11 | 200 | 0.2 | 300 | 10 | 100 | 0.305 |
| 12 | 400 | 0.35 | 300 | 50 | 100 | 0.213 |
| 13 | 600 | 0.2 | 300 | 50 | 100 | 0.176 |
| 14 | 200 | 0.5 | 300 | 10 | 100 | 0.280 |
| 15 | 600 | 0.5 | 300 | 50 | 500 | 0.406 |
| 16 | 600 | 0.2 | 300 | 30 | 100 | 0.179 |
| 17 | 200 | 0.5 | 300 | 30 | 300 | 0.313 |
| 18 | 400 | 0.2 | 300 | 10 | 300 | 0.604 |
| 19 | 200 | 0.35 | 300 | 10 | 500 | 0.457 |
| 20 | 600 | 0.5 | 300 | 50 | 500 | 0.480 |
| 21 | 400 | 0.35 | 250 | 30 | 300 | 0.553 |
| 22 | 600 | 0.35 | 250 | 10 | 100 | 0.531 |
| 23 | 200 | 0.5 | 250 | 50 | 100 | 0.260 |
| 24 | 600 | 0.2 | 250 | 50 | 300 | 0.294 |
| 25 | 200 | 0.2 | 250 | 30 | 500 | 0.393 |
| 26 | 400 | 0.5 | 250 | 10 | 500 | 1.105 |
| 27 | 600 | 0.5 | 300 | 10 | 500 | 1.262 |

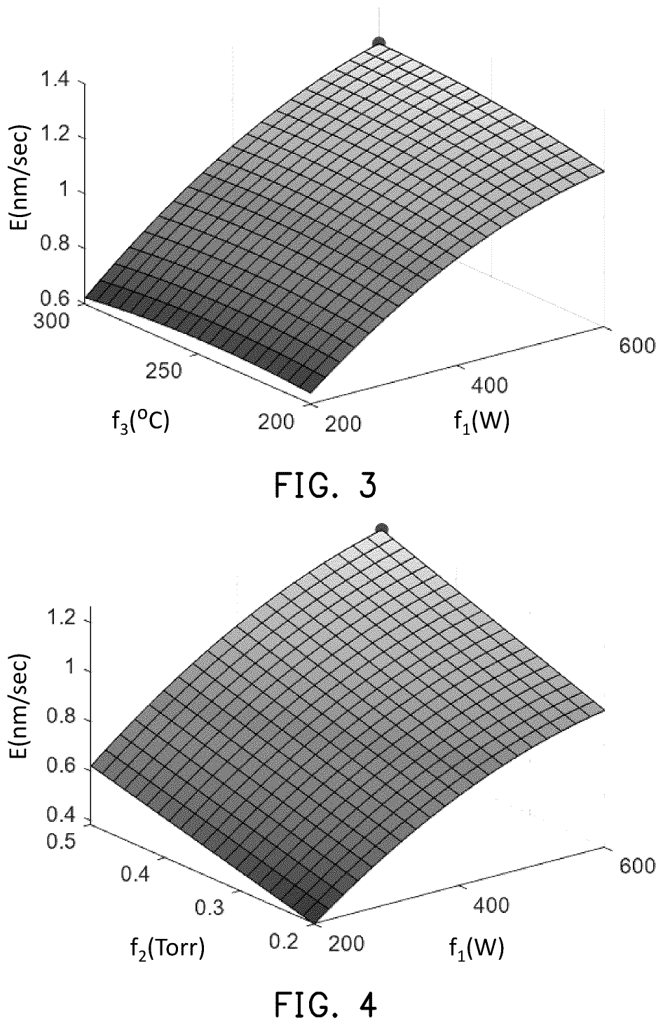

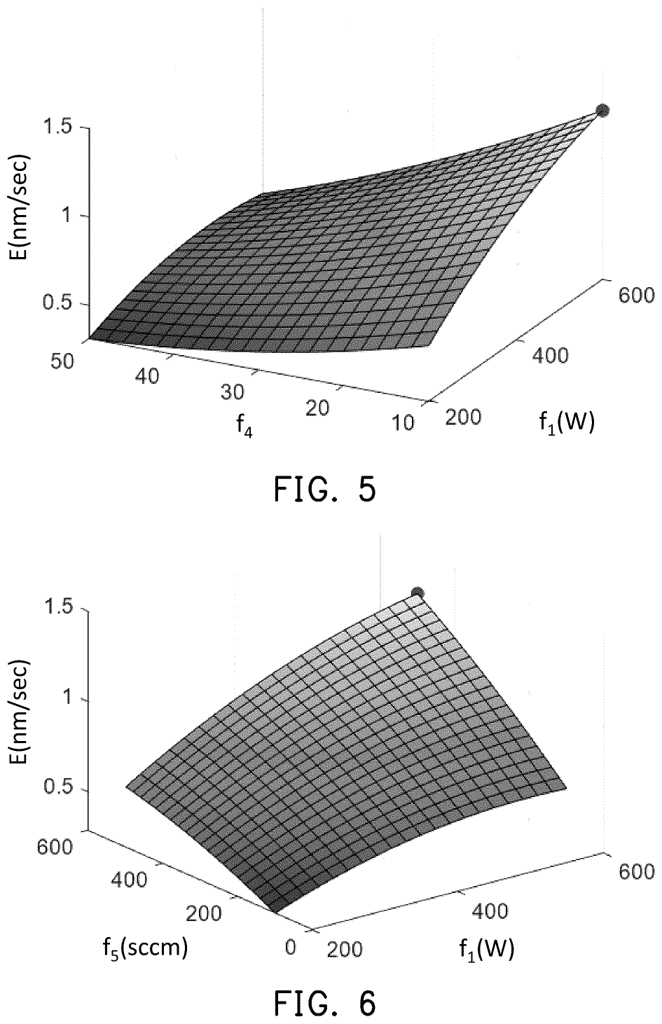

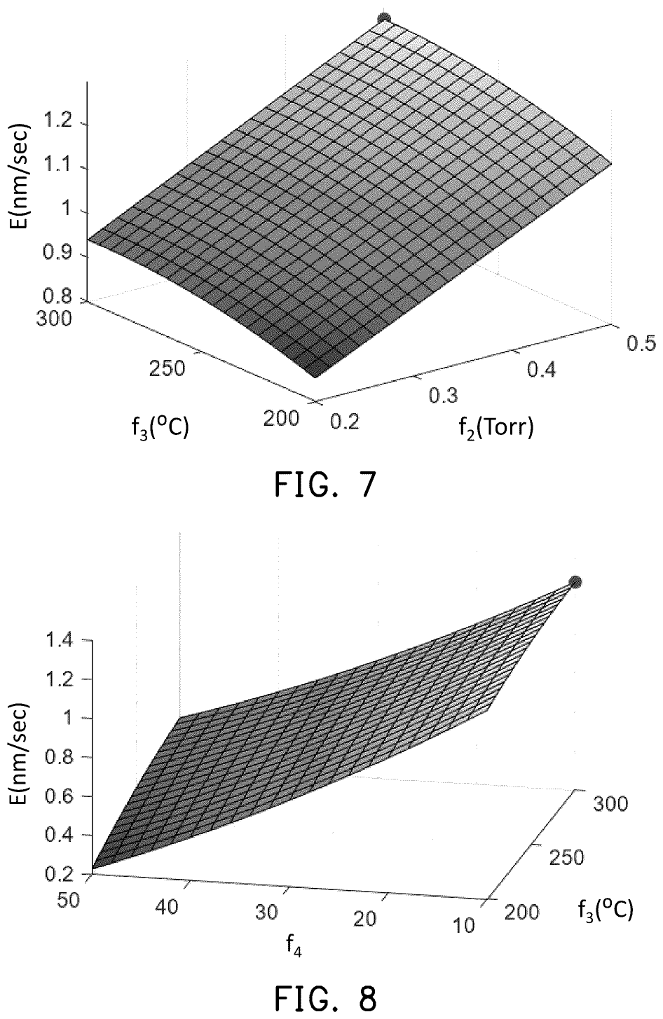

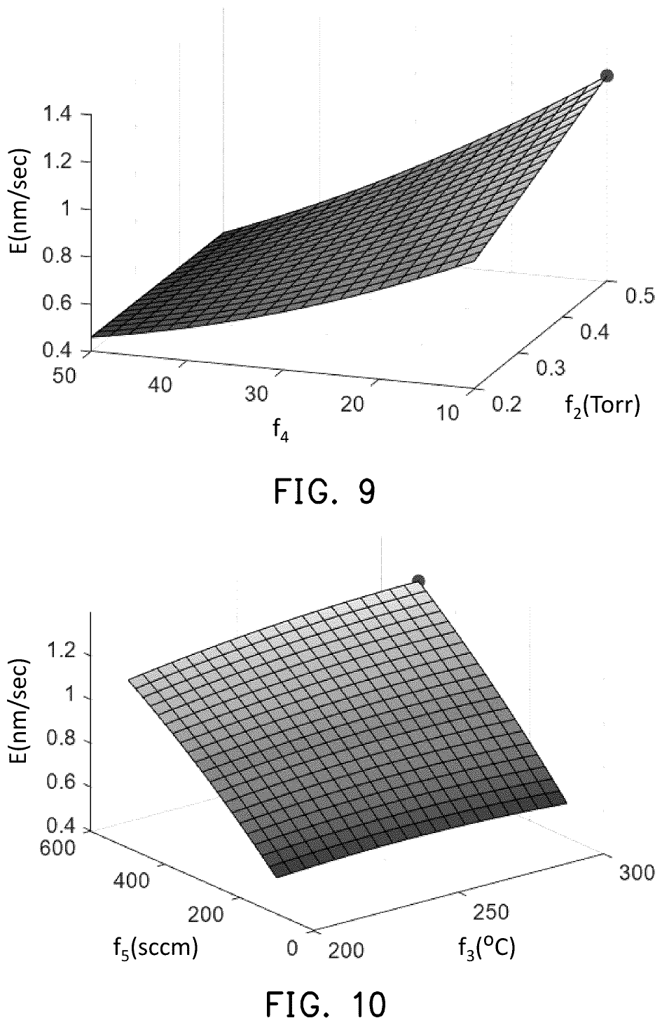

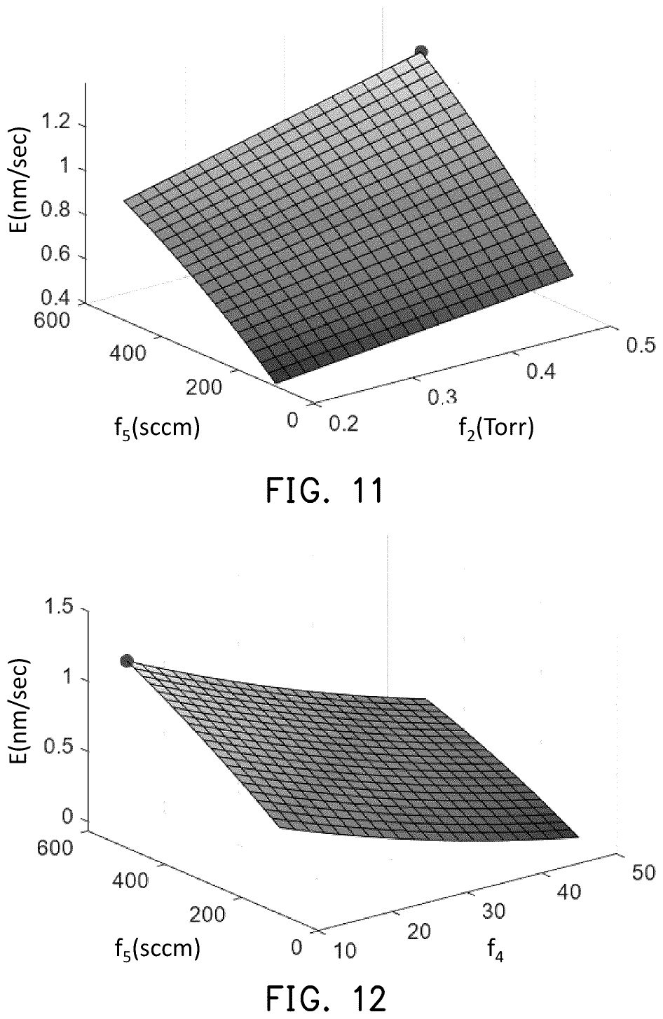

A multi-dimensional response surface diagram is illustrated according to the best fitting function obtained above, as shown in FIG. 3 to FIG. 12. FIG. 3 is a three-dimensional surface diagram of RF power, substrate temperature, and deposition rate according to an experiment example. FIG. 4 is a three-dimensional surface diagram of RFpower, reaction chamber pressure, and deposition rate according to an experiment example. FIG. 5 is a three-dimensional surface diagram of RF power, flow ratio of N₂ and SiH₄, and deposition rate according to an experiment example. FIG. 6 is a three-dimensional surface diagram of RF power, mass flow rate of N₂, and deposition rate according to an experiment example. FIG. 7 is a three-dimensional surface diagram of substrate temperature, reaction chamber pressure, and deposition rate according to an experiment example. FIG. 8 is a three-dimensional surface diagram of flow ratio of N₂ and SiH₄, substrate temperature, and deposition rate according to an experiment example. FIG. 9 is a three-dimensional surface diagram of flow ratio of N₂ and SiH₄, reaction chamber pressure, and deposition rate according to an experiment example. FIG. 10 is a three-dimensional surface diagram of mass flow rate of N₂, substrate temperature, and deposition rate according to an experiment example. FIG. 11 is a three-dimensional surface diagram of reaction chamber pressure, mass flow rate of N₂, and deposition rate according to an experiment example. FIG. 12 is a three-dimensional surface diagram of flow ratio of N₂ and SiH₄, mass flow rate of N₂, and deposition rate according to an experiment example.

The obtained best fitting function shows that the mass flow rate of N₂ and the reaction chamber pressure are the parameters that have a greater impact on the thin film deposition rate, while the interaction term between the flow ratio of N₂ and SiH₄ and the substrate temperature has the greatest impact on the thin film deposition rate.

In addition, from the three-dimensional surface diagrams in FIG. 3 to FIG. 12, it can be predicted that the optimal process parameter combination within the above process range is 600 W of RF power, 0.5 Torr of reaction chamber pressure, 300° C. of substrate temperature, 10M of flow ratio of N₂ and SiH₄, and 500 sccm of mass flow rate N₂ to achieve a film deposition rate of 1.2665 nm/sec. The optimal process parameter combination was verified through experiment and the actual thin film deposition rate was 1.262 nm/sec, which is similar to the predicted thin film deposition rate, confirming the good predictability of the method.

It can be seen that this experiment example can obtain the fitting function that can well describe the deposition rate of silicon nitride thin film through 27 sets of experiment data and determine its optimal process parameter combination, which can improve the efficiency of the film process control, and if there are different needs for the deposition rate (e.g., a specific deposition rate), the corresponding process parameter combination can be quickly found through the obtained fitting function.

To sum up, the optimization method for the vacuum plating process of the disclosure can fit a small amount of experiment data to obtain an accurate fitting function by fitting the multi-dimensional quadratic transformation function and making dynamic iterative corrections. In this way, the efficiency of optimization and the accuracy of prediction may be effectively improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An optimization method for a vacuum plating process, comprising:
determining a property of a thin film to be optimized;
according to the property of the thin film to be optimized, determining process parameters and a level of each of the process parameters;
according to the process parameters and the level of the each of the process parameters, designing M sets of experiments, wherein M is a positive integer, M is positively related to a number of the process parameters, but M is not related to a number of the level of the process parameters;
performing the M sets of experiments to obtain M sets of test films, and measuring or calculating the property of each of the test films;
fitting process parameters used in the M sets of experiments and the property of the M sets of test films with a multi-dimensional quadratic transformation function to obtain a first fitting function;
dynamically modifying the first fitting function using an iteration method to obtain a best fitting function; and
illustrating a multi-dimensional response surface diagram using the best fitting function to determine an optimal process parameter combination.

2. The optimization method for the vacuum plating process according to claim 1, wherein an extrapolation difference method is used to expand analysis of the multi-dimensional response surface diagram to a full space to determine the optimal process parameter.

3. The optimization method for the vacuum plating process according to claim 1, wherein the best fitting function is represented by the following formula 1,
$$E = ( {c}_{0 , 0} + Δ {c}_{0} ) + {\sum }_{i = 1}^{n} ( {c}_{i , 0} + Δ {c}_{i} ) {f}_{i} + {\sum }_{i = 1}^{n} ( {c}_{ii , 0} + Δ {c}_{ii} ) {f}_{i}^{2} + {\sum }_{i = 1}^{n} {\sum }_{j = 1}^{n} ( {c}_{ij , 0} + Δ {c}_{ij} ) {f}_{i} {f}_{j} , \qquad [ Formula 1 ]$$
where E is the property of the thin film to be optimized, n is the number of the process parameters, fᵢ and fⱼ are the process parameters, and c_{0,0}, c_{i,0}, c_{ii,0}, and c_{ij,0} are coefficients obtained by fitting the data of the M sets of experiments,
$$Δ {c}_{0} is {\sum }_{k = 1}^{p} ( {c}_{0 , k} - {c}_{0 , k - 1} ) , Δ {c}_{i , k} is {\sum }_{k = 1}^{p} ( {c}_{i , k} - {c}_{i , k - 1} ) , \\ Δ {c}_{ii , k} is {\sum }_{k = 1}^{p} ( {c}_{ii , k} - {c}_{ii , k - 1} ) , Δ {c}_{ij , k} is {\sum }_{k = 1}^{p} ( {c}_{ij , k} - {c}_{ij , k - 1} ) ,$$
where c_{0,k}, c_{i,k}, C_{ii,k}, and C_{ij,k} are coefficients obtained by a k^{th} iteration and fit, c_{0,k-1}, c_{i,k-1}, C_{ii,k-1}, and c_{ij,k-1} are coefficients obtained by a k−1^{th} iteration and fit, and p is a number of iterations.

4. The optimization method for the vacuum plating process according to claim 3, wherein M is at least (n²+3n+2)/2.

5. The optimization method for the vacuum plating process according to claim 3, wherein at least M+p sets of experiments are required to obtain the best fitting function.

6. The optimization method for the vacuum plating process according to claim 1, wherein the experiment design adopts an orthogonal array composite design method.

7. The optimization method for the vacuum plating process according to claim 1, wherein the process parameters comprise a process pressure, a process temperature, a reactant flow rate, a type of reactant, a reactant addition ratio, and/or a radio frequency power.

8. The optimization method for the vacuum plating process according to claim 1, wherein a determination coefficient of the first fitting function is smaller than a determination coefficient of the best fitting function.

9. The optimization method for the vacuum plating process according to claim 1, wherein the property of the thin film to be optimized comprises a thickness, a residual stress, a deposition rate, uniformity, a refractive index, a resistance value, and/or a proportion of a component of the thin film.

10. The optimization method for the vacuum plating process according to claim 1, wherein the vacuum plating process comprises physical vapor deposition, thermal evaporation, electron beam evaporation, ion beam assisted evaporation, molecular beam epitaxy growth, pulse laser coating, chemical vapor deposition, plasma enhanced chemical vapor deposition, metal organic chemical vapor deposition, and atomic layer deposition.
